(19) United States
(12) Patent Application Publication
(10) Pub. No.: US 2005/0078465 A1
(43) Pub. Date: Apr. 14, 2005

(54) Chassis base unit for plasma display device and plasma display device including the chassis base unit

(76) Inventor: Sok-San Kim, Suwon-si (KR)

Correspondence Address: Robert E. Bushnell;Suite 300, 1522 K Street, N.W., Washington, DC, 20005-1202, US

(21) Appl. No.: 10/960,490

(22) Filed: Oct. 8, 2004

(30) Foreign Application Priority Data
Oct. 9, 2003 (KR) 10-2003-0070246

(51) Int. Cl. H05K 7/14; H05K 7/18

(52) U.S. Cl. 361/797

(57) ABSTRACT

A chassis base unit and a plasma display device including the chassis base unit has: a chassis base having a plurality of edges including two adjacent edges, each of the two adjacent edges having a side wall formed at a predetermined angle with respect to an interior plane of the chassis base, the side walls of the two adjacent edges being separated; and an ear member or connecting member separate from the chassis base, the ear member or connecting member attached to the chassis base at a corner between the two adjacent edges.

### CLAIM OF PRIORITY

This application makes reference to, incorporates the same herein, and claims all benefits accruing under 35 U.S.C. §119 from an application for CHASSIS BASE UNIT FOR PLASMA DISPLA YDEVICEAND PLASMA DISPLA YDEVICE USING THE SAME earlier filed in the Korean Intellectual Property Office on 9 Oct. 2003 and there duly assigned Serial No. 10-2003-0070246.

### BACKGROUND OF THE INVENTION

1. Field of the Invention

The present invention relates to a chassis base unit for a plasma display device and a plasma display device including the chassis base unit. More particularly, the present invention relates to a chassis base unit having enhanced production efficiency and stiffness, and a plasma display device including such a chassis base unit.

2. Description of the Related Art

As is well known in the art, a plasma display device realizes a desired image using a plasma discharge. Such a plasma display device generally includes a Plasma Display Panel (PDP) for realizing the desired image through a plasma discharge activated by an external power source, a chassis base for firmly holding the PDP on its front side, and circuit boards mounted on a rear side of the chassis base for driving the PDP.

Auxiliary components in addition to the PDP and circuit boards can also be combined with the chassis base. For example, front and rear cover panels can be attached to a module (frequently called a PDP module) formed as a conjunction of the PDP, the circuit boards, and the chassis base.

Therefore, in many cases, ears are formed at corners of the chassis base such that such auxiliary components can be attached thereto. That is, at a same conjoining structure of the PDP and circuit boards to the chassis base, the chassis base can optionally require ears at corners thereof according to the specifications of the plasma display device.

According to the prior art, ears of a chassis base are integrally formed to the chassis base. Therefore, in order to meet the two different requirements, different chassis bases are manufactured according to whether ears are required at corners of a chassis base, although they can have the same interior structure except for the ears. Furthermore, when a different set of ears are required, a different chassis base is necessarily manufactured for each set of ears.

Therefore, production efficiency of a plasma display device can significantly increase when a chassis base of a plasma display device can be manufactured in a single shape regardless of whether ears are required at corners thereof.

In addition, a chassis base is required to have sufficient stiffness (or rigidity) to firmly hold a PDP and circuit boards. For sufficient stiffness, each edge of a chassis base is bent almost perpendicular to an interior plane of the chassis base. However, when ears are integrally formed on a chassis base, such bent edges can not be interconnected. The stiffness (especially torsional stiffness) of a chassis base can be significantly enhanced when such bent edges are firmly interconnected.

A plasma display device using such a chassis base having enhanced production efficiency and stiffness also has enhanced production efficiency and stiffness.

The information disclosed in this Background of the Invention section is only for the enhancement of understanding of the background of the invention and should not be taken as an acknowledgment or any form of suggestion that this information forms the prior art that is already known in this country to a person of ordinary skill in the art.

### SUMMARY OF THE INVENTION

An object of the present invention is to provide a chassis base having enhanced production efficiency and stiffness, and to provide a plasma display device including such a chassis base.

These and other objects can be achieved by providing a chassis base unit comprising: a chassis base having a plurality of edges including two adjacent edges, each of the two adjacent edges having a side wall formed at a predetermined angle with respect to an interior plane of the chassis base, the side walls of the two adjacent edges being separated; and an ear member separate from the chassis base, the ear member attached to the chassis base at a corner between the two adjacent edges.

The side wall is preferably bent at a corresponding edge of the chassis base.

The side walls of the two adjacent edges are preferably attached together by the ear member.

The ear member is also preferably attached to the interior plane of the chassis base.

The ear member comprises first and second side walls preferably attached to each other and wherein the side walls of the two adjacent edges are respectively preferably attached to the first and second side walls of the ear member.

These and other objects can also be achieved by providing a chassis base unit comprising: a chassis base having a plurality of edges including two adjacent edges, each of the two adjacent edges having a side wall formed at a predetermined angle with respect to an interior plane of the chassis base, the side walls of the two adjacent edges being separated; and a connecting member separate from the chassis base, the connecting member attaching the two adjacent edges together.

The side wall is preferably bent at a corresponding edge of the chassis base.

The connecting member comprises first and second side walls preferably attached to each other and wherein the side walls of the two adjacent edges are preferably respectively attached to the first and second side walls of the connecting member.

The connecting member is preferably attached to the interior plane of the chassis base.

The connecting member is preferably attached to the chassis base at a corner between the two adjacent edges.

The connecting member preferably comprises a portion outwardly protruding from an outer circumference of the chassis base and wherein at least one through-hole is preferably arranged at an interior of the outwardly protruding portion.

These and other objects can also be achieved by providing a plasma display device comprising: a chassis base unit; a plasma display panel mounted on the chassis base unit; and at least one printed circuit board mounted on the chassis base unit, wherein the chassis base unit comprises: a chassis base having a plurality of edges including two adjacent edges, each of the two adjacent edges having a side wall bent at a predetermined angle with respect to an interior plane of the chassis base, the side walls of the two adjacent edges being separated; and an ear member separate from the chassis base, the ear member attached to the chassis base at a corner between the two adjacent edges.

These and other objects can also be achieved by providing a plasma display device comprising: a chassis base unit; a plasma display panel mounted on the chassis base unit; and at least one printed circuit board mounted on the chassis base unit, wherein the chassis base unit comprises: a chassis base having a plurality of edges including two adjacent edges, each of the two adjacent edges having a side wall bent at a predetermined angle with respect to an interior plane of the chassis base, the side walls of the two adjacent edges being separated; and a connecting member separate from the chassis base, the connecting member attaching the two adjacent edges together.

### BRIEF DESCRIPTION OF THE DRAWINGS

A more complete appreciation of the present invention, and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a schematic diagram of a plasma display device according to an embodiment of the present invention;

FIG. 2 is enlarged perspective view of a portion A of FIG. 1 according to a first embodiment of the present invention;

FIG. 3 is a perspective view of FIG. 2 seen in a direction B;

FIG. 4 is an exploded view of FIG. 2;

FIG. 5 is enlarged perspective view of a portion A of FIG. 1 according to a second embodiment of the present invention;

FIG. 6 is a perspective view of FIG. 5 seen in a direction C;

FIG. 7 is enlarged perspective view of a portion A of FIG. 1 according to a third embodiment of the present invention; and

FIG. 8 is a perspective view of FIG. 7 seen in a direction D.

### DETAILED DESCRIPTION OF THE INVENTION

Embodiments of the present invention will hereinafter be described in detail with reference to the accompanying drawings.

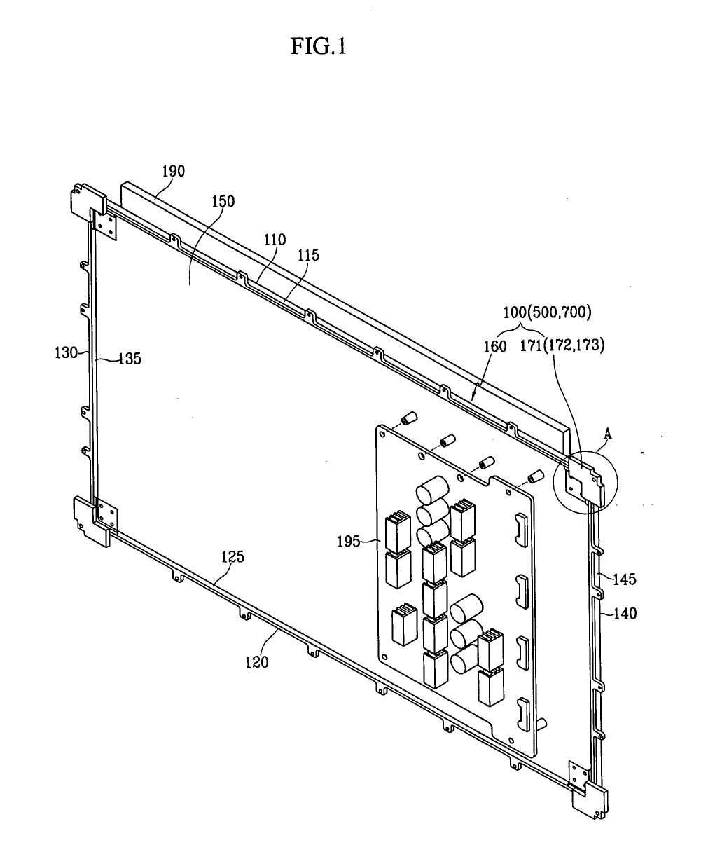

FIG. 1 is a schematic diagram of a plasma display device according to an embodiment of the present invention.

As shown in FIG. 1, a plasma display device according to an embodiment of the present invention includes a chassis base unit 100 according to an embodiment of the present invention, a Plasma Display Panel (PDP) 190 mounted on the chassis base unit 100, and at least one Printed Circuit Board (PCB) 195 mounted on the chassis base unit 100.

The chassis base unit 100 according to an embodiment of the present invention includes a chassis base 160 and an ear member 171.

The chassis base 160 includes four edges 110, 120, 130, and 140 at upper, lower, left, and right sides of an interior plane 150 thereof. Therefore, the chassis base 160 includes four pairs of two adjacent edges 110 and 130, 130 and 120, 120 and 140, and 140 and 110. The edges 110, 120, 130, and 140 are bent at a predetermined angle (e.g., 90 degrees) with respect to the interior plane 150, and respectively form side walls 115, 125, 135, and 145.

Hereinafter, side walls of the upper, lower, left, and right edges 110, 120, 130, and 140 are respectively referred to as first, second, third, and fourth side walls 115, 125, 135, and 145.

The upper and lower edges 110 and 120 can be symmetrically formed, and the left and right edges 130 and 140 can also be symmetrically formed. In addition, features hereinafter described with respect to a corner between the upper and right edges 110 and 140 can be symmetrically applied to corners between the upper and left edges 110 and 130, the left and lower edges 130 and 120, and the right and lower edges 140 and 120.

Therefore, the chassis base unit 100 according to an embodiment of the present invention is described in detail with respect to features of the corner between the upper and right edges 110 and 140. Features of other corners are obvious to a person of ordinary skill in the art from the description hereinafter.

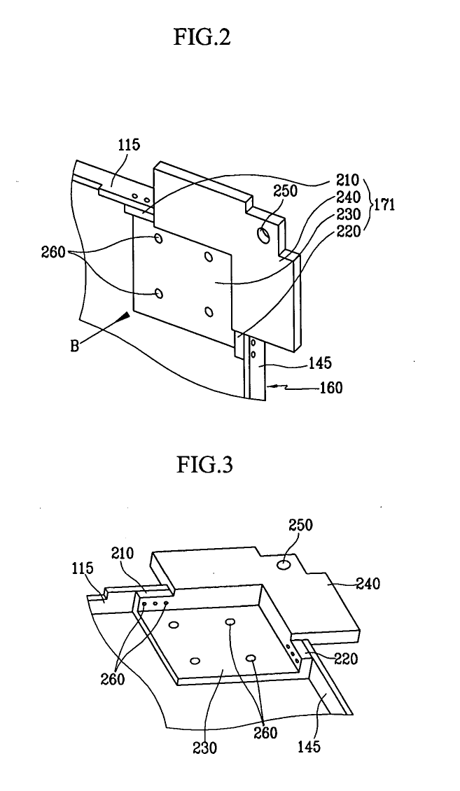

FIG. 2 is enlarged perspective view of a portion A of FIG. 1 according to a first embodiment of the present invention.

FIG. 3 is a perspective view of FIG. 2 seen in a direction B.

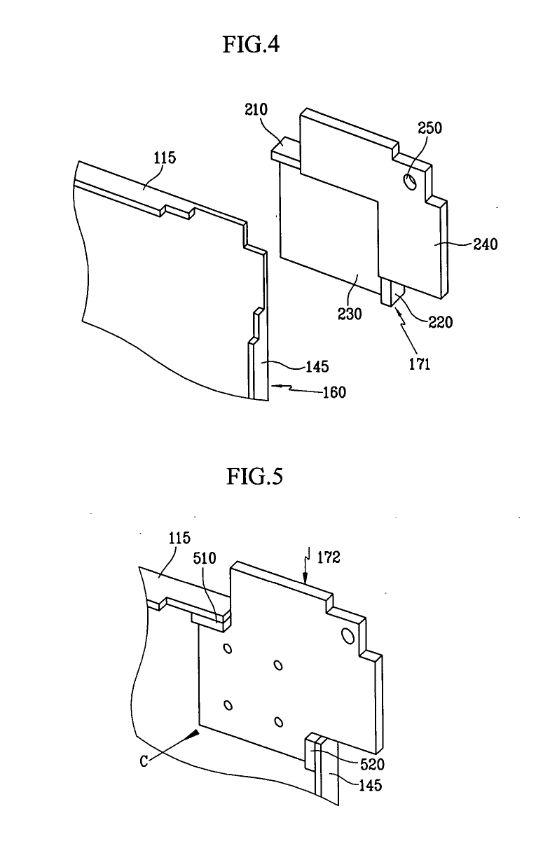

FIG. 4 is an exploded view of FIG. 2.

As shown in FIG. 2 to FIG. 4, the chassis base unit 100 according to an embodiment of the present invention includes the chassis base 160 and the ear member 171.

The first side wall 115 (i.e., the side wall of the upper edge 110) and the fourth side wall 145 (i.e., the side wall of the right edge 140) of the chassis base 160 are respectively bent perpendicularly to the interior plane 150 of the chassis base 160. In addition, the first and fourth side walls 115 and 145 are separated with respect to each other.

The ear member 171 is attached to the chassis base 160 at the corner between the upper and right edges 110 and 140.

The ear member 171 has side walls 210 and 220 at upper and right sides thereof. The upper side wall 210 and the right side wall 220 are interconnected to each other, and they are formed perpendicular to a base plate 230 of the ear member 171.

The first side wall 115 of the chassis base 160 is attached to the upper side wall 210 of the ear member 171, and the fourth side wall 145 of the chassis base 160 is attached to the right sidewall 220 of the ear member 171. In addition, the base plate 230 of the ear member 171 is attached to the interior plane 150 of the chassis base 160.

Since the chassis base 160 and the ear member 171 are attached through the side walls 115, 145, 210, and 220, the strength thereof can be enhanced. In addition, since the two side walls 210 and 220 of the ear member 171 are attached, the chassis base unit 100 having the chassis base 160 and the attached ear member 171 has enhanced stiffness (especially torsional stiffness).

In addition, stiffness around a corner can be further enhanced since the base plate 230 of the ear member 171 is attached to the interior plane 150 of the chassis base 160.

According to such a chassis base unit 100 of an embodiment of the present invention, the ear member 171 can be regarded as a connecting member (which is therefore hereinafter denoted with the same reference number 171) connecting the side walls 115 and 145 of the two adjacent edges 110 and 140 of the chassis base 160. Since the two side walls 115 and 145 are connected, rigidity of the chassis base unit 100 is enhanced.

Utility of an interior space of the chassis base unit 100 is enhanced since such a connecting member 171 is attached to the corner between the two adjacent edges 110 and 140 of the chassis base 160.

In addition, the connecting member 171 has a protruding portion 240 outwardly protruding from an outer circumference of the chassis base 160, and at least one through-hole 250 is formed at an interior of the protruding portion 240 such that an auxiliary component (not shown) can be mounted therethrough.

According to the chassis base unit 100 of an embodiment of the present invention, attachment of the chassis base 160 to the ear member 171 (i.e., the connecting member 171) can be realized by any firm attachment scheme, such as screw engagement, riveting, and/or welding, at points 260.

The shape of the protruding portion 240 and a position of the through-hole 250 of the ear member 171, (i.e., the connecting member 171) can be variously changed in accordance with a required specification.

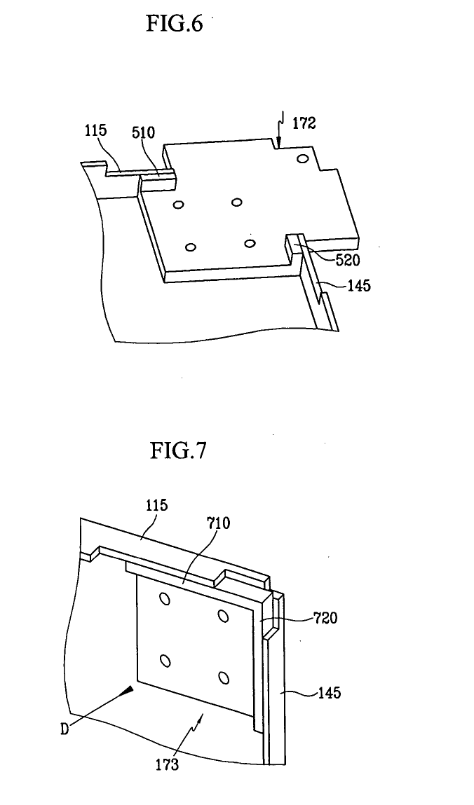

A chassis base unit according to a second embodiment of the present invention is hereinafter described in detail with reference to FIG. 5 and FIG. 6.

FIG. 5 is enlarged perspective view of a portion A of FIG. 1 according to a second embodiment of the present invention, and FIG. 6 is a perspective view of FIG. 5 seen in a direction C.

Various features described in connection with the chassis base unit 100 of a first embodiment of the present invention are also commonly realized by a chassis base unit 500 according to a second embodiment of the present invention, and such common features of the first and second embodiments are apparent to a person of ordinary skill in the art with reference to FIGS. 5 and 6.

Unlike the first embodiment, as shown in FIGS. 5 and 6, the side walls 510 and 520 of an ear member 172 (i.e., a connecting member 172) are not attached, according to a chassis base unit 500 of the second embodiment of the present invention.

Nevertheless, the chassis base unit 500 according to the second embodiment can realize various merits of the first embodiment, based on features common with the first embodiment. For example, it can realize an enhancement of production efficiency of plasma display devices that can be achieved by the usage of an ear member 172 manufactured separately from the chassis base 160.

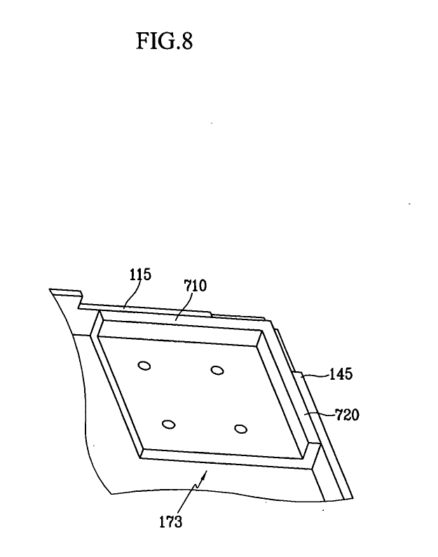

A chassis base unit according to a third embodiment of the present invention is hereinafter described in detail with reference to FIG. 7 and FIG. 8.

FIG. 7 is enlarged perspective view of a portion A of FIG. 1 according to a third embodiment of the present invention, and FIG. 8 is a perspective view of FIG. 7 seen in a direction D.

Various features described in connection with the chassis base unit 100 of a first embodiment of the present invention are also commonly realized by a chassis base unit 700 according to a third embodiment of the present invention, and such common features of the first and third embodiments are apparent to a person of ordinary skill in the art with reference to FIGS. 7 and 8.

Unlike the first embodiment, as shown in FIGS. 7 and 8, a connecting member 173 according to a chassis base unit 700 of the third embodiment of the present invention is not provided with a protruding portion that outwardly protrudes to an outer circumference of the chassis base 160.

Nevertheless, the chassis base unit 700 according to the third embodiment can realize various merits of the first embodiment, based on features common with the first embodiment. For example, stiffness of a plasma display device becomes enhanced since two side walls 115 and 145 of the chassis base are firmly attached by two side walls 710 and 720 of the connecting member 173. Furthermore, such a chassis base unit 700 can also realize an enhancement of production efficiency of plasma display devices that can be achieved by the usage of an ear member 173 manufactured separately from the chassis base 160.

As can be seen from the above described chassis base units 100, 500, and 700 according to first, second, and third embodiments, the same chassis base 160 can be used to realize various types of chassis base units 100, 500, and 700, simply by changing ear members (or connecting members) 171, 172, and 173.

According to the present invention, various types of chassis base units are realized by attaching connecting members of various shapes and/or ear members at corners between adjacent edges of a same chassis base.

In addition, rigidity of a chassis base and accordingly a plasma display device can be enhanced by attaching adjacent side walls of the chassis base. In particular, rigidity of a chassis base and a plasma display device can be further enhanced when a connecting member attaching adjacent side walls of the chassis base is provided with side walls attached to each other such that the side walls of the chassis base are attached though the side walls of the connecting members.

While this invention has been described in connection with exemplary embodiments, it is to be understood that the present invention is not limited to the disclosed embodiments, but on the contrary, is intended to cover various modifications and equivalent arrangements included within the spirit and scope of the appended claims.

1. A chassis base unit comprising:
a chassis base having a plurality of edges including two adjacent edges, each of the two adjacent edges having a side wall formed at a predetermined angle with respect to an interior plane of the chassis base, the side walls of the two adjacent edges being separated; and
a connecting member attaching the two adjacent edges together.

2. The chassis base unit of claim 1, wherein the side wall is bent at a corresponding edge of the chassis base.

3. The chassis base unit of claim 1, wherein the connecting member comprises first and second side walls attached to each other and wherein the side walls of the two adjacent edges are respectively attached to the first and second side walls of the connecting member.

4. The chassis base unit of claim 3, wherein the connecting member is attached to the interior plane of the chassis base.

5. The chassis base unit of claim 3, wherein the connecting member is attached to the chassis base at a corner between the two adjacent edges.

6. The chassis base unit of claim 5, wherein the connecting member comprises a portion outwardly protruding from an outer circumference of the chassis base and wherein at least one through-hole is arranged at an interior of the outwardly protruding portion.

7. A chassis base unit comprising:
a chassis base having a plurality of edges including two adjacent edges, each of the two adjacent edges having a side wall formed at a predetermined angle with respect to an interior plane of the chassis base, the side walls of the two adjacent edges being separated; and
an ear member separate from the chassis base, the ear member attached to the chassis base at a corner between the two adjacent edges.

8. The chassis base unit of claim 7, wherein the side wall is bent at a corresponding edge of the chassis base.

9. The chassis base unit of claim 7, wherein the side walls of the two adjacent edges are attached together by the ear member.

10. The chassis base unit of claim 9, wherein the ear member is also attached to the interior plane of the chassis base.

11. The chassis base unit of claim 7, wherein the ear member comprises first and second side walls attached to each other and wherein the side walls of the two adjacent edges are respectively attached to the first and second side walls of the ear member.

12. A plasma display device comprising:
a chassis base unit;
a plasma display panel mounted on the chassis base unit; and
at least one printed circuit board mounted on the chassis base unit, wherein the chassis base unit comprises:
a chassis base having a plurality of edges including two adjacent edges, each of the two adjacent edges having a side wall bent at a predetermined angle with respect to an interior plane of the chassis base, the side walls of the two adjacent edges being separated; and
an ear member separate from the chassis base, the ear member attached to the chassis base at a corner between the two adjacent edges.

13. A plasma display device comprising:
a chassis base unit;
a plasma display panel mounted on the chassis base unit; and
at least one printed circuit board mounted on the chassis base unit, wherein the chassis base unit comprises:
a chassis base having a plurality of edges including two adjacent edges, each of the two adjacent edges having a side wall bent at a predetermined angle with respect to an interior plane of the chassis base, the side walls of the two adjacent edges being separated; and
a connecting member separate from the chassis base, the connecting member attaching the two adjacent edges together.
